(19) United States
(12) Patent Application Publication
(10) Pub. No.: US 2015/0236179 A1
(43) Pub. Date: Aug. 20, 2015

(54) FILTERING DEFECTS WITH STRAIN-COMPENSATED MULTI-LAYER QUANTUM DOTS

(71) Applicant: Jun Yang, Maumee, OH (US)

(72) Inventor: Jun Yang, Maumee, OH (US)

(21) Appl. No.: 14/628,219

(22) Filed: Feb. 21, 2015

Related U.S. Application Data
(60) Provisional application No. 61/941,597, filed on Feb. 19, 2014.

(51) Int. Cl. H01L 31/0352; H01L 31/0304; H01L 33/32; H01L 33/04; H01L 33/30

(52) U.S. Cl. CPC H01L 31/035236; H01L 33/04; H01L 33/30; H01L 33/32; H01L 31/035218; H01L 31/0304; H01L 31/03044; H01L 31/03046; H01L 31/03048

(57) ABSTRACT

The invention disclosed an approach of fabricating high quality semiconductor layers during the epitaxial growth by utilizing strain-compensated multiple layers of quantum dots to block the dislocation propagation and trap the defects. Such strain compensation scheme is achieved by inserting the inverse strained layer into the quantum dot dislocation filters. It, therefore, can maximize the filtering of dislocations and other defects.

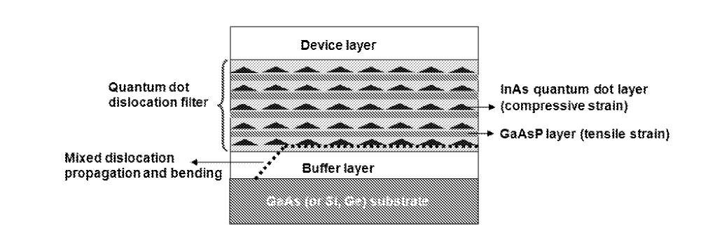

### BACKGROUND

The use of strained superlattices (SLS) has been demonstrated as an effective method to filter dislocations by bending their propagation. The bending enables the threading dislocations annihilation or transport to the sample edge, therefore resulting in a reduction of the defect density [1]. Alternatively, strain-driven self-organized quantum dots could reduce the defect density [2]. Further, it is pointed out that the only use of large size and multiple layers of quantum dots could effectively accomplish such defect reduction [3]. The quantum dot defect filter has two advantages as compared with SLS [3]. It can block both the mixed dislocations and pure edge dislocations, the latter cannot be blocked by SLS. On the other hand, point defects tend to be trapped in a localized strain region beneath the quantum dots due to the local strain energy minimization. So, the quantum dot defect filters are shown a powerful approach to block the existing defects in the epitaxial growth of high-quality optoelectronics devices including lasers, detectors, LEDs, solar cells, and other electronic and RF devices.

### DESCRIPTION AND SUMMARY

The growth of large size and multiple layers of quantum dots will accumulate epitaxial layer strains which ultimately induces additional misfit dislocations. So, the number of layers is required to be limited [3]. To enhance the filtering effect, this invention proposes an insert of the inverse strained layer between the quantum dot layers. Such strain controlled scheme in terms of strain compensation or balance would allow more layers of quantum dots to be grown, therefore maximizing the filtering of dislocations and other defects. An example of such structure inserting compensated or balanced strain layers of GaAsP into the InAs quantum dot defect filters is illustrated in the figure. Self-organized grown InAs quantum dots on GaAs (or Si, Ge) substrates have compressive strain while the inserted GaAsP thin layers have tensile strains. Therefore, such a strain-compensated quantum dot dislocation filter would enhance the reduction of defects meanwhile avoiding the generation of new defects and misfit dislocations.

### REFERENCES

1) N. A. EL-Masry, J. C. Tarn and N. H. Karam, “Interactions of Dislocations in GaAs grown on Si substrates with InGaAs-GaAsP Strained layered superlattices,” J. Appl. Phys., vol.64, no.7, pp.3672-3677, 1988.

2) U.S. Patent U.S. 20020013042, Defect reduction in GaN and related materials.

3) J. Yang, P. Bhattacharya, and Z. Mi, “High-performance In0.5Ga0.5As/GaAs quantum-dot laser on silicon with multiple-layer quantum-dot dislocation filters,” IEEE Trans. Electron Dev., vol.54, no.11, pp. 2849-2855, 2007.

### CAPTION OF DRAWINGS

The illustration of quantum dot defect filters consisting of multiple layers of InAs quantum dots and strain-compensated or balanced layers of GaAsP, wherein a mixed-dislocation is propagating to meet quantum dot filters and get bending.

What is claimed:

1. A defect filter consists of multiple epitaxial layers which comprising:
Strain-driven self-organized semiconductor quantum dots (or islands, boxes) with coherent strain as strong as possible;
Semiconductor layer with reverse strain relative to quantum dots (or islands, boxes), which is inserted between quantum dot layers

2. The dislocation filter of claim 1 is inserted into an epitaxial structure consisting of a substrate and a series of epitaxial layers like buffer, contact, cladding, waveguide, active layers and so on. The dislocation filter of claim 1 can be located below or above a certain region of high density defects. The dislocation filter of claim 1 blocks the dislocation and other defects like point defects propagating up-ward or down-ward into device active region.

3. The quantum dots (or islands, boxes) of claim 1 are formed by the epitaxial growth of a semiconductor material with lattice mismatch (exceeding about 1.8%) relative to the underlying material. The induced strain due to the lattice mismatch enables the self-organized three-dimensional growth to form many dots, island or box, having the dimension size of 1-10 nanometer or more or less, and the strong built-in strain existed both inside and in the surrounding region.

4. The material of claim 1 wherein said quantum dot (or islands, boxes) are made of an material selected from the various groups consisting of 1) GaN-based GaN, AN, InN, AlGaN, InGaN, and combinations thereof; 2) GaAs-based GaAs, AlAs, InAs, InGaAs, AlGaAs, InAlAs, and combinations thereof; 3) InP-based InP, InGaP, GaAsP, InAlGaP, and combinations thereof; 4) Si/Ge; 5) other materials can achieve strain-driven self-organized dots (or islands, boxes) of claims 1 and 3.

5. The composition of the quantum dots (or islands, boxes) of claims 1 and 4 is selected, having coherent strain and as more as possible, to create larger size, strain and higher density of quantum dots (or islands, boxes) of claims 1 and 4 to enhance the defect reduction.

6. The semiconductor layers with reverse strain of claim 1 are formed by the epitaxial growth of a selected semiconductor material of claim 4 with a reverse lattice mismatch relative to the underlying material.

7. The semiconductor layers with reverse strain of claim 1 wherein the location is arbitrary, can be between every two layers of quantum dots of claim 1, or every three layers, or every more layers, or randomly among the layers of quantum dots of claim 1.

8. The selection of layer number, thickness, and material composition of the semiconductor layers with reverse strain of claim 1 is wide as long as the total strain is controlled to avoiding the generation of additional defects or dislocations. However, if achieving complete strain compensation or balance, a dedicated selection is required.
